(19) United States
(12) Patent Application Publication
(10) Pub. No.: US 2026/0317905 A1
(43) Pub. Date: Oct. 15, 2026

(54) isolation plate for use in semiconductor processing chamber and related methods

(71) Applicant: Applied Materials, Inc., Santa Clara, CA (US)

(72) Inventors: Ala MORADIAN, Sunnyvale, CA (US); Chandra MOHAPATRA, San Jose, CA (US); Mostafa BAGHBANZADEH, Oakland, CA (US); John TOLLE, Gilbert, AZ (US); Zhepeng CONG, San Jose, CA (US)

(21) Appl. No.: 19/645,461

(22) Filed: Apr. 13, 2026

Related U.S. Application Data
(60) Provisional application No. 63/788,277, filed on Apr. 14, 2025.

(51) Int. Cl. C23C 16/455; C23C 16/458; C23C 16/46; C30B 25/10; C30B 25/14; H10P 72/76

(52) U.S. Cl. CPC C23C 16/45591; C23C 16/4583; C23C 16/46; C30B 25/10; C30B 25/14; H10P 72/7604

(57) ABSTRACT

In one or more embodiments, a processing chamber includes a first plate, a second plate, and a plurality of sidewalls at least partially defining a processing volume. A cover is disposed above the first plate. The cover and the first plate at least partially define an upper heating area. A first energy module is disposed within the upper heating area. The first energy module comprises a plurality of heating elements. A substrate support is disposed in the processing volume. A plurality of ribs are disposed around the first plate, the second plate, and the sidewalls. A plurality of shelves are disposed opposite of one another within the processing volume. An isolation plate is disposed within the processing volume and above the substrate support. An outer portion of a lower surface of the isolation plate supported by the plurality of shelves.

### CROSS-REFERENCE TO RELATED APPLICATION

This Application claims the benefit of U.S. Provisional Application 63/788,277 filed on Apr. 14, 2025, which is hereby incorporated by reference herein.

### BACKGROUND

### Field

Embodiments of the present disclosure generally relate to a semiconductor processing chamber, and more particularly, an isolation plate configured to improve a precursor deposition uniformity within a processing chamber, and related methods.

### Description of the Related Art

Semiconductor substrates are processed for a wide variety of applications, including the fabrication of integrated devices and micro-devices. One method of processing substrates includes depositing a material, such as a dielectric material or a semiconductive material, on an upper surface of the substrate. The material may be deposited in a lateral flow chamber by flowing a process gas parallel to the surface of a substrate positioned on a support, and thermally decomposing the process gas to deposit a material from the gas onto the substrate surface. However, during a deposition process, a vortex can form along the surface of the substrate due to substrate rotation. The vortex prevents a uniform process gas flow over the substrate, which affects the deposition quality and uniformity over the substrate.

Therefore, a need exists for improved process chamber components and related methods that facilitate depositing a material that is more uniform in thickness.

### SUMMARY

Embodiments of the present disclosure generally relate to a semiconductor processing chamber, and more particularly, an isolation plate configured to improve a precursor deposition uniformity within a processing chamber, and related methods.

In one or more embodiments, a processing chamber includes a first plate, a second plate, and a plurality of sidewalls at least partially defining a processing volume. A cover is disposed above the first plate. The cover and the first plate at least partially define an upper heating area. A first energy module is disposed within the upper heating area. The first energy module comprises a plurality of heating elements. A substrate support is disposed in the processing volume. A plurality of ribs are disposed around the first plate, the second plate, and the sidewalls. A plurality of shelves are disposed opposite of one another within the processing volume. An isolation plate is disposed within the processing volume and above the substrate support. An outer portion of a lower surface of the isolation plate supported by the plurality of shelves.

In one or more embodiments, a process kit includes a substrate support and ring sized and shaped to surround the substrate support. The process kit further includes a plurality of support shelves. The shelves respectively include a block having a thickness lesser than a length. The process kit further includes an isolation plate sized and shaped for disposition on the plurality of support shelves.

In one or more embodiments, a method of loading an isolation plate includes disposing a substrate onto a substrate support within a processing volume using a robot arm and disposing an isolation plate on a plurality of support shelves disposed within the processing volume using the robot arm. The method further includes heating the substrate positioned on the substrate support and flowing one or more process gases over the substrate to process the substrate. The flowing of the one or more process gases over the substrate includes guiding the one or more process gases through one or more flow paths defined at least in part by a space between the isolation plate and the substrate.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only exemplary embodiments and are therefore not to be considered limiting of its scope, and may admit to other equally effective embodiments.

FIG. 1 is a partial schematic side cross-sectional view of a processing chamber, according to one or more embodiments.

FIG. 2 is a schematic cross sectional side view of a process chamber, according to one or more embodiments.

FIG. 3 is a schematic cross sectional front view of the process chamber shown in FIG. 2, according to one or more embodiments.

FIG. 4, is a schematic isometric view of an isolation plate disposed on a plurality of support shelves within the processing chamber, according to one or more embodiments.

FIG. 5 is a schematic isometric view of an isolation plate disposed on a plurality of support shelves, according to one or more embodiments.

FIG. 6 is a schematic block diagram of a method of loading an isolation plate within a processing volume of the processing chamber, according to one or more embodiments.

FIGS. 7A and 7B are schematic cross sectional side views of the process chamber, according to embodiments.

FIG. 8 is a schematic top view of an isolation plate, according to embodiments.

FIG. 9 is a schematic cross sectional front view of the process chamber, according to one or more embodiments.

FIG. 10 cross sectional side views of the process chamber 2000, according to embodiments.

To facilitate understanding, identical reference numerals have been used, where possible, to designate identical elements that are common to the figures. It is contemplated that elements and features of one embodiment may be beneficially incorporated in other embodiments without further recitation.

### DETAILED DESCRIPTION

The present disclosure relates to a semiconductor processing chamber, and more particularly, an isolation plate configured to improve a precursor deposition uniformity within a processing chamber, and related methods.

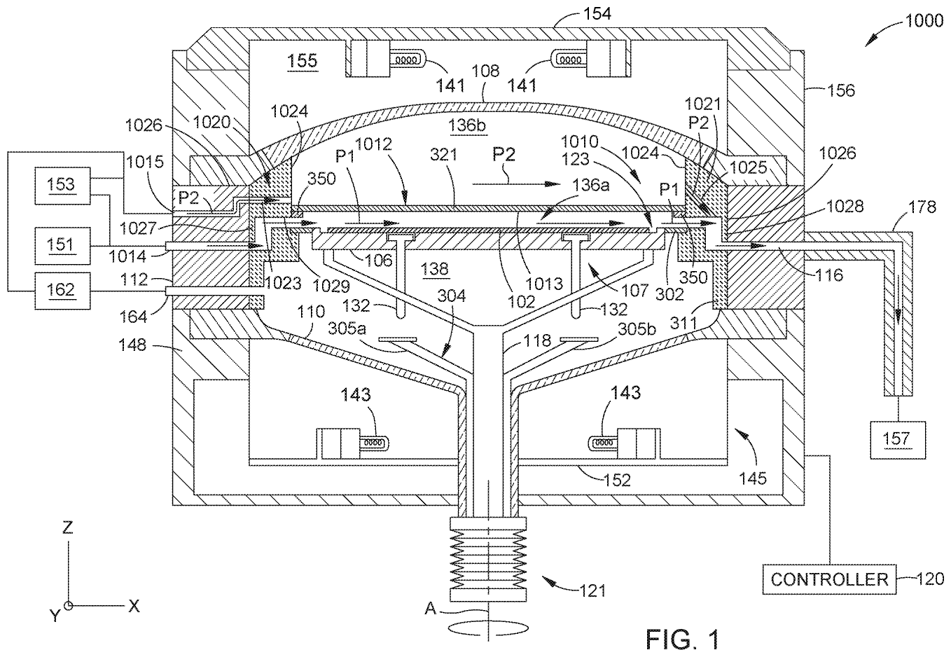

FIG. 1 is a partial schematic side cross-sectional view of a processing chamber 1000, according to one or more embodiments. The processing chamber 1000 is a deposition chamber. In one or more embodiments, the processing chamber 1000 is an epitaxial deposition chamber. The processing chamber 1000 is utilized to grow an epitaxial film on a substrate 102. The processing chamber 1000 creates a cross-flow of precursors across a top surface of the substrate 102. The processing chamber 1000 is shown in a processing condition in FIG. 1.

The processing chamber 1000 includes an upper body 156, a lower body 148 disposed below the upper body 156, a flow module 112 disposed between the upper body 156 and the lower body 148. The upper body 156, the flow module 112, and the lower body 148 form a chamber body. Disposed within the chamber body is a substrate support 106, an upper window 108 (such as an upper dome), a lower window 110 (such as a lower dome), a plurality of upper heat sources 141, and a plurality of lower heat sources 143. As shown, a controller 120 is in communication with the processing chamber 1000 and is used to control processes and methods, such as the operations of the methods described herein. The present disclosure contemplates that each of the heat sources described herein can include one or more of: lamp(s), resistive heater(s), light emitting diode(s) (LEDs), and/or laser(s). The present disclosure contemplates that other heat sources can be used.

The substrate support 106 is disposed between the upper window 108 and the lower window 110. The substrate support 106 includes a support face 123 that supports the substrate 102. The plurality of upper heat sources 141 are disposed between the upper window and a lid 154. The plurality of upper heat sources 141 form a portion of the upper heat source module 155. The lid 154 may include a plurality of sensors disposed therein or thereon for measuring the temperature within the processing chamber 1000. The plurality of lower heat sources 143 are disposed between the lower window 110 and a floor 152. The plurality of lower heat sources 143 form a portion of a lower heat source module 145. In one or more embodiments, the upper window 108 is an upper dome and is formed of an energy transmissive material, such as quartz. In one or more embodiments, the lower window 110 is a lower dome and is formed of an energy transmissive material, such as quartz. A pre-heat ring 302 is disposed outwardly of the substrate support 106. The pre-heat ring 302 is supported on a ledge of the lower liner 311. A stop 304 includes a plurality of arms 305a, 305b that each include a lift pin stop on which at least one of the lift pins 132 can rest when the substrate support 106 is lowered (e.g., lowered from a process position to a transfer position).

The internal volume has the substrate support 106 disposed therein. The substrate support 106 includes a top surface on which the substrate 102 is disposed. The substrate support 106 is attached to a shaft 118. The shaft 118 is connected to a motion assembly 121. The motion assembly 121 includes one or more actuators and/or adjustment devices that provide movement and/or adjustment for the shaft 118 and/or the substrate support 106.

The substrate support 106 may include lift pin perforations 107 disposed therein. The lift pin perforations 107 are sized to accommodate a lift pin 132 for lifting of the substrate 102 from the substrate support 106 either before or after a deposition process is performed.

A process kit 1010 includes an isolation plate 321 having a first face 1012 and a second face 1013 opposing the first face 1012. The second face 1013 faces the substrate support 106. The process kit 1010 includes an upper liner 1020. The upper liner 1020 includes an section 1021. The upper liner 1020 includes one or more inlet openings 1023 extending to an inner surface 1024 of the section 1021 on a first side of the upper liner 1020, and one or more outlet openings 1025 extending to the inner surface 1024 of the section 1021 on a second side of the upper liner 1020.

The one or more inlet openings 1023 extend from an outer surface 1026 of the section 1021 of the upper liner 1020 to the inner surface 1024. The one or more outlet openings 1025 extend from a lower surface 1029 of the upper liner 1020 to the inner surface 1024. The upper liner 1020 includes a first extension 1027 and a second extension 1028 disposed outwardly of the lower surface 1029 of the upper liner 1020. At least part of the section 1021 of the upper liner 1020 is aligned with the first extension 1027 and the second extension 1028. In the embodiment shown in FIG. 1, a lowermost end of the isolation plate 321 is aligned above a lowermost end of the upper liner 1020. In one or more embodiments, as shown in FIG. 1, the lowermost end of the isolation plate 321 is part of the second face 1013, and the lowermost end of the upper liner 1020 is part of the first extension 1027 and/or the second extension 1028. The present disclosure contemplates that the lowermost end of the upper liner 1020 can be part of the lower surface 1029.

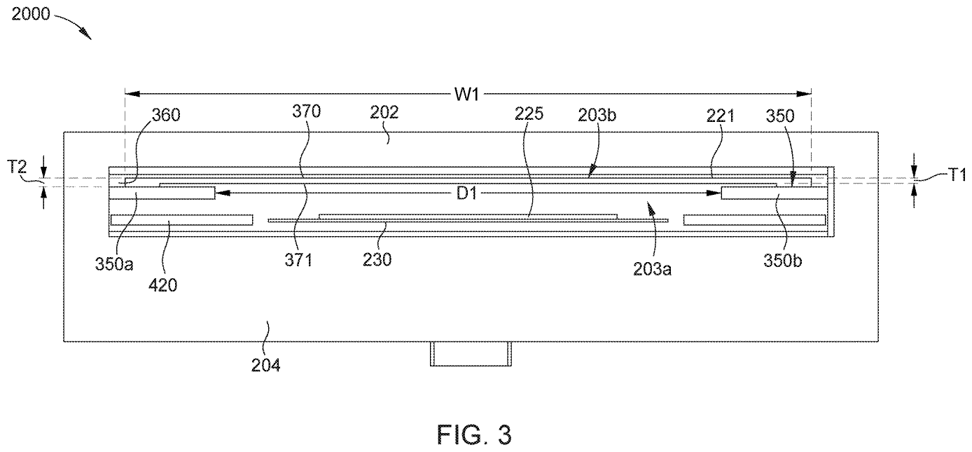

In one or more embodiments, the isolation plate 321 is in the shape of a disc, and the section 1021 is in the shape of a ring. It is contemplated, however, that the isolation plate 321 and/or the section 1021 can be in the shape of a rectangle, or other geometric shapes. The isolation plate 321 at least partially fluidly isolates the upper portion 136b from the lower portion 136a. The lower portion 136a has a smaller volume than the upper portion 136b. A ratio of the volume of the lower portion 136a relative to the volume of the upper portion 136 b can be less than 0.25. Other values (such as 0.25 or higher) can be used for the ratio. In one or more embodiments, one or more shelves 350 are coupled to the upper liner 1020. The isolation plate 321 is supported by the one or more shelves 350. The shelves 350 are described in greater detail in FIG. 3.

The flow module 112 (which can define at least part of one or more sidewalls of the processing chamber 1000) includes one or more first inlet openings 1014 in fluid communication with the lower portion 136a of the processing volume. The flow module 112 includes one or more second inlet openings 1015 in fluid communication with the upper portion 136b of the processing volume. The one or more first inlet openings 1014 are in fluid communication with one or more flow gaps between the upper liner 1020 and the lower liner 311. The one or more second inlet openings 1015 are in fluid communication with the one or more inlet openings 1023 of the upper liner 1020. The one or more inlet openings 1014 are fluidly connected to one or more process gas sources 151 and one or more cleaning gas sources 153. The purge gas inlet(s) 164 are fluidly connected to one or more purge gas sources 162. The one or more exhaust outlets 116 are fluidly connected to an exhaust pump 157. One or more process gases supplied using the one or more process gas sources 151 can include one or more reactive gases (such as one or more of silicon-containing, phosphorus-containing, and/or germanium-containing gases, and/or one or more carrier gases (such as one or more of nitrogen (N₂) and/or hydrogen (H₂)). One or more purge gases supplied using the one or more purge gas sources 162 can include one or more inert gases (such as one or more of argon (Ar), helium (He), and/or nitrogen (N₂)). One or more cleaning gases supplied using the one or more cleaning gas sources 153 can include one or more of hydrogen and/or chlorine. In one or more embodiments, the one or more process gases include silicon phosphide (SiP) and/or phospine (PH₃), and the one or more cleaning gases include hydrochloric acid (HCl).

The one or more exhaust outlets 116 are further connected to or include an exhaust system 178. The exhaust system 178 fluidly connects the one or more exhaust outlets 116 and the exhaust pump 157. The exhaust system 178 can assist in the controlled deposition of a layer on the substrate 102. The exhaust system 178 is disposed on an opposite side of the processing chamber 1000 relative to the flow module 112. The one or more inlet openings 1014 are configured to direct a gas (such as the process gas(es) P1) across a gas flow path over the substrate support 106 and to the one or more exhaust outlets 116.

In one or more embodiments, as shown in FIG. 1, the one or more inlet openings 1023 are oriented in a horizontal orientation and the one or more outlet openings 1025 are oriented in an angled orientation. The present disclosure contemplates that the one or more inlet and/or outlet openings 1023, 1025 can be oriented in a horizontal orientation, oriented in an angled (e.g., non-parallel to horizontal) orientation, and/or can include one or more turns (such as the turns shown for the one or more first inlet openings 1014 and the one or more exhaust outlets 116).

During a deposition operation (e.g., an epitaxial growth operation), the one or more process gases P1 flow through the one or more first inlet openings 1014, through the one or more gaps, and into the lower portion 136a of the processing volume to flow across a gas flow path over the substrate 102. During the deposition operation, one or more purge gases P2 flow through the one or more second inlet openings 1015, through the one or more inlet openings 1023 of the upper liner 1020, and into the upper portion 136b of the processing volume. The one or more purge gases P2 flow simultaneously with the flowing of the one or more process gases P1. The flowing of the one or more purge gases P2 through the upper portion 136b facilitates reducing or preventing flow of the one or more process gases P1 into the upper portion 136b that would contaminate the upper portion 136b. The one or more process gases P1 are exhausted through gaps between the upper liner 1020 and the lower liner 311, and through the one or more exhaust outlets 116. The one or more purge gases P2 are exhausted through the one or more outlet openings 1025, through the same gaps between the upper liner 1020 and the lower liner 311, and through the same one or more exhaust outlets 116 as the one or more process gases P1. The present disclosure contemplates that that one or more purge gases P2 can be separately exhausted through one or more second gas exhaust outlets that are separate from the one or more exhaust outlets 116.

The present disclosure also contemplates that one or more purge gases can be supplied to the purge volume 138 (through the plurality of purge gas inlets 164) during the deposition operation, and exhausted from the purge volume 138.

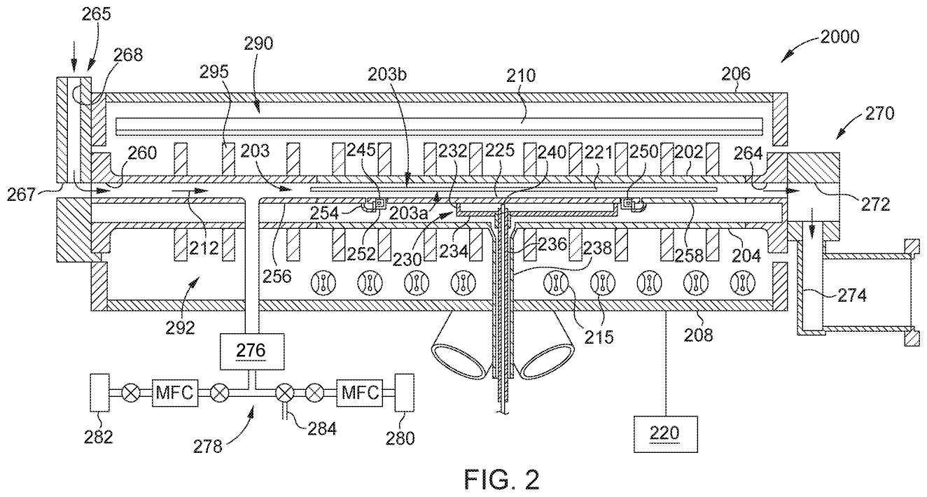

FIG. 2 is a schematic cross sectional side view of a process chamber 2000, according to one or more embodiments. The process chamber 2000 is similar at least in some respects to the process chamber 1000 shown in FIG. 1. The process chamber 2000 may generally have the shape of a rectangular box. The process chamber 2000 includes a first plate 202, a second plate 204. In one or more, the first plate 202 and the second plate 204 are connected by a plurality of inner sidewalls to form an inner rectangular box defining a inner volume 203. The first plate 202 and the second plate 204 may be fabricated from the same material as the upper window 108 and the lower window 110 shown in FIG. 1. In the implementation of FIG. 2, the first and second plates 202 and 204 are flat, and made of quartz transparent to the wavelength of energy to be passed therethrough to heat a substrate.

A first energy module 210 is disposed above the first plate 202. The first energy module 210 may include a plurality of radiant heat sources, for example linear heat sources, such as elongated tube-type radiant heating elements. In one or more embodiments, the first energy module 210 includes a plurality of spaced-apart linear lamps. The first energy module 210 is disposed in an upper heating area 290. The upper heating area 290 is at least partially defined by the first plate 202 and a cover 206 disposed above the first energy module 210. The first energy module 210 is disposed in spaced-apart parallel relationship and also extend substantially perpendicular to a reactant gas flow path (shown by arrow 212) through the process chamber 2000. A second energy module 215 is positioned below the second plate 204, and oriented transverse to the first energy module 210. The second energy module 215 is disposed in a lower heating area 292. The lower heating area 292 is at least partially defined by the second plate 204 and chamber bottom 208 located below the second energy module 215. The second energy module 215 may include a plurality of radiant heat sources, for example linear heat sources, such as elongated tube-type radiant heating elements. In one or more embodiments, the second energy module 215 includes a plurality of spaced-apart second linear lamps. In one or more embodiments, the second linear lamps of the second energy module 215 are oriented parallel to a direction of process gas flow in the inner volume 203, and the linear lamps of the first energy module 210 are oriented perpendicularly to the direction of process gas flow.

In one or more embodiments, the cover 206 and chamber bottom 208 at least partially define an outer rectangular box. The inner rectangular box is disposed within the outer rectangular box. The inner rectangular box and the outer rectangular box at least partially define the upper heating area 290 and the lower heating area 292.

A substrate 225 is shown supported by a substrate support 230 disposed in the inner volume 203. The substrate support 230 includes a substrate holder 232, upon which the substrate 225 rests, and a support spider 234. The spider 234 is mounted to a shaft 236, which extends downwardly through a tube 238 extending through a chamber bottom 208. The tube 238 communicates with a source of purge gas which can flow therethrough during processing of the substrate 225.

An isolation plate 221 is disposed within the processing volume. In one or more embodiments, the isolation plate 221 is similar to the isolation plate 321 shown in FIG. 1. In one or more embodiments, the isolation plate 221 is in the shape of a rectangle. The isolation plate 221 is described further in FIG. 3. The isolation plate 221 at least partially fluidly isolates an upper inner volume 203b of the inner volume 203 from a lower inner volume 203a of the inner volume 203.

In one or more embodiments, a plurality of ribs 295 are disposed within the upper heating area 290 and the lower heating area 292. In one or more embodiments, the ribs 295 wrap around the first plate 202, the second plate 204, and the inner sidewalls 360 (FIG. 3). The ribs 295 provide structural support for the around the first plate 202, the second plate 204, and the inner sidewalls 360 (FIG. 3) defining the inner volume 203. In one or more embodiments, the ribs 295 are formed of the same material as the first plate 202 and the second plate 204. In one or more embodiments, the ribs 295 are formed of a quartz transparent to the wavelength of energy to be passed therethrough to heat a substrate.

A plurality of temperature sensors is positioned in proximity to the substrate 225. The temperature sensors may take a variety of forms, such as optical pyrometers or thermocouples. In the illustrated embodiment, the temperature sensors comprise thermocouples, including a first or central thermocouple 240, suspended below the substrate holder 232 in any suitable fashion. The central thermocouple 240 passes through the spider 234 in proximity to the substrate holder 232. The process chamber 2000 further includes a plurality of secondary or peripheral thermocouples, also in proximity to the substrate 225, including a leading edge or front thermocouple 245, a trailing edge or rear thermocouple 250, and a side thermocouple. Each of the peripheral thermocouples is housed within a slip ring 252, which surrounds the substrate holder 232 and the substrate 225. The slip ring 252 rests upon support members 254, which extend from a front chamber divider 256 and a rear chamber divider 258. The dividers 256, 258 are fabricated from quartz. Each of the central and peripheral thermocouples are connected to a temperature controller, which sets the power of the various heat sources 210, 215 in response to the temperature readings from the thermocouples.

The process chamber 2000 further includes an inlet port 260 for the injection of reactant and carrier gases, and the substrate 225 can also be received therethrough. An outlet port 264 is on the opposite side of the process chamber 2000, with the substrate support structure 230 positioned between the inlet port 260 and outlet port 264. An inlet component 265 is fitted to the process chamber 2000, adapted to surround the inlet port 260, and includes a horizontally elongated slot 267 through which the substrate 225 can be inserted. A generally vertical inlet 268 receives gases from gas sources and communicates such gases with the slot 267 and the inlet port 260. An outlet component 270 similarly mounts to the process chamber 2000 such that an exhaust opening 272 aligns with the outlet port 264 and leads to exhaust conduits 274. The exhaust conduits 274, in turn, can communicate with suitable vacuum means (not shown) for exhausting process gases from the process chamber 2000.

The process chamber 2000 also includes a species source 276 of excited species, positioned below the chamber bottom 208. The excited species source 276 may be a remote plasma generator disposed along a gas line 278. A source of precursor gases is coupled to the gas line 278 for introduction into the excited species source 276. A source 282 of carrier gas is also coupled to the gas line 278. One or more branch lines 284 can also be provided for additional reactants. The excited species source 276 can be employed for plasma enhanced deposition, but also may be utilized for exciting etchant gas species for cleaning the process chamber 2000 of excess deposition material when no substrate is in the process chamber 2000. The present disclosure contemplates that the species source 276 and the associated lines 278, 284 and sources 280, 282 can be omitted from the process chamber 2000.

The above-described process chamber 2000 can be controlled by a processor based system controller, such as controller 220, shown in FIG. 2. For example, the controller 220 is configured to control flow of various precursor and process gases and purge gases from gas sources, during different operations of a substrate processing sequence.

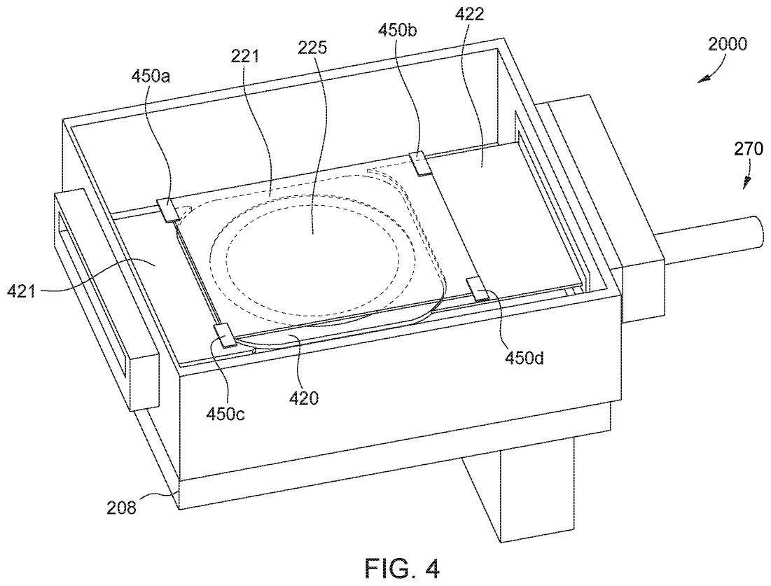

FIG. 3 is a schematic cross sectional front view of the process chamber 2000 shown in FIG. 2, according to one or more embodiments. In one or more embodiments, the isolation plate 221 is a rectangular plate. In one or more embodiments, the isolation plate 221 is a square plate. The isolation plate 221 is supported by a plurality of shelves 350. In one or more embodiments, the shelves 350 are formed of the same material as the first plate 202 and or the second plate 204. In one or more embodiments, the plurality of shelves 350 are disposed along opposite sides of the substrate support 230. In one or more embodiments, the shelves 350 are coupled to the inner sidewalls 360 of the inner volume 203. In one or more embodiments, the shelves 350 are coupled to the substrate support 230. In one or more embodiments, the shelves 350 are coupled to a ring 420 (FIG. 4), such as a cover ring and/or a pre-heat ring, surrounding the substrate support 230. In one or more embodiments, the thickness of each shelf 350 is less than the length of each shelf 350.

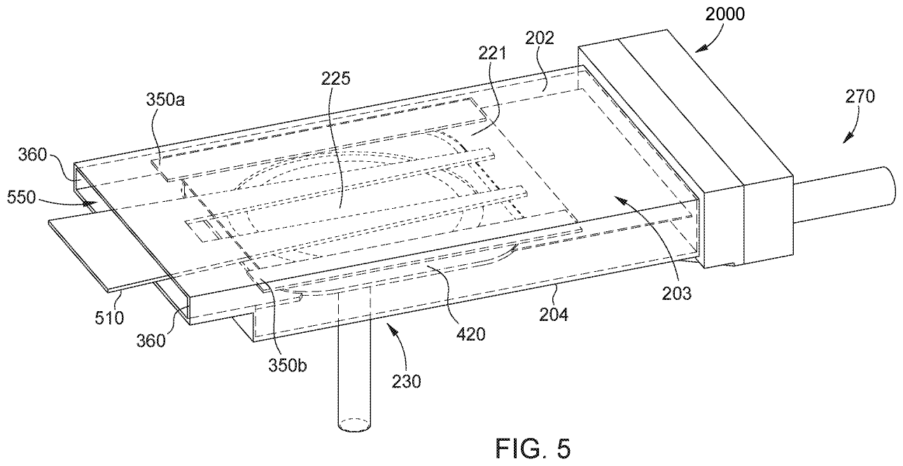

The plurality of shelves 350 includes at least a first shelf 350a and a second shelf 350b. The first shelf 350a and the second shelf 350b are separated by a first distance D1. The first shelf 350a and the second shelf 350b are spaced from each other on opposite sides of the processing chamber 2000. The isolation plate 221 has a first width W1. The first width W1 is greater than the first distance D1. During an isolation plate loading operation, a robot arm 510 (FIG. 5) insets the isolation plate into the inner volume 203. The robot arm 510 disposes the isolation plate 221 on the plurality of shelves 350. An outer portion of the lower surface 371 of the isolation plate is supported by each shelf 350. In one or more embodiments, the isolation plate 221 directly contacts the shelves 350. The isolation plate 221 can be fixed to the shelves 350, or can rest on the shelves 350 such that the isolation plate 221 is removable by overcoming gravitational forces. The isolation plate 221 at least partially defines the lower inner volume 203a (e.g., a process volume) and the upper inner volume 203b. The reactant gas flow path is configured to flow across the substrate support 230 within the lower inner volume 203a. The isolation plate 221 lowers a distance between the upper surface of the substrate support 230 and an upper surface of the process volume. The lower distance can increase the velocity of the reactant gas flow. The increase velocity may reduce the boundary layer thickness and reduced the effect of a rotational vortex induced by rotating wafer, which improves the deposition quality.

In one or more embodiments, the isolation plate 221 is a flat plate. In one or more embodiments, the isolation plate 221 has an inner thickness T1 of an inner section and an outer thickness T2 of an outer section disposed radially outwardly of the inner section. The inner thickness can be less than the outer thickness, as shown in FIG. 3. It is contemplated that in one or more embodiments, the inner thickness T1 is greater than the outer thickness T2. The isolation plate 221 has an upper surface 370 and a lower surface 371. In one or more embodiments, the upper surface 370, the lower surface 371, or a combination thereof have a curved geometry, a jagged geometry, and/or a trenched geometry.

FIG. 4, is a schematic isometric view of an isolation plate 221 disposed on a plurality of support shelves within the processing chamber 2000, according to one or more embodiments. It should be understood that the processing chamber 2000 shown in FIG. 4 does not include the first plate 202, the second plate 204, or the inner sidewalls 360 for illustrative purposes.

As shown in FIG. 4, in one or more embodiments, the processing chamber includes four support shelves 450a-450d. The support shelves 450a-450d are similar to the shelves 350 described in FIG. 3. The support shelves 450a-450d are each disposed within the processing chamber 2000 and are configured to support a portion of the lower surface of the isolation plate 221. For example, as shown in FIG. 4, the first shelf 450a and the second shelf 450b are disposed along a first side of the processing chamber 2000. The third shelf 450c and the fourth shelf 450d are disposed along a second side of the processing chamber 2000. The first side of the processing chamber 2000 and the second side of the processing chamber 2000 are located opposite of one another. The isolation plate 221 is disposed on the shelves 450a-450d. In one or more embodiments, the each of the shelves 450a-450d are configured to support a different corner of the isolation plate 221. For example, the first shelf 450a supports a first corner of the isolation plate 221. The second shelf 450b supports a second corner of the isolation plate 221. The third shelf 450c supports a third corner of the isolation plate 221. The fourth shelf 450d supports a fourth corner of the isolation plate 221. The present disclosure contemplates that other regions of the isolation plate 221 can be supported by the shelves 450a-450d. In one or more embodiments, the shelves 450a-450d are blocks, such as rectangular blocks. Other shapes are contemplated for the shelves 450a-450d. For example, the shelves 450a-450d can be linear and/or arcuate.

In one or more embodiments, each of the shelves 450a-450d are coupled (such as welded or otherwise coupled) to the inner sidewalls 360. In one or more embodiments, each of the shelves 450a-450d are coupled (such as welded or otherwise coupled) to the ring 420 and/or outer plate(s) 421, 422 disposed outwardly of the ring 420.

FIG. 5 is a schematic isometric view of an isolation plate 221 disposed on a plurality of shelves 350a, 350b, according to one or more embodiments. As shown in FIG. 5, in one or more embodiments, the first shelf 350a and the second shelf 350b are disposed within the inner volume 203 opposite to one another. The substrate 225 is disposed between and below the shelves 350a, 350b. The robot arm 510 is configured to load the isolation plate 221 into the inner volume 203 through an opening 550. The gap formed between the substrate 225 and the isolation plate 221 is larger than a thickness of the robot arm 510 in order to allow the robot arm 510 to retreat from the inner volume 203 without contacting ether the substrate 225 or the isolation plate 221. It should be understood that although the shelves 350a 350b are shown being coupled to the inner sidewalls 360, the support shelves may be coupled anywhere within the processing volume, including the first plate 202, the second plate 204, or the ring 420. Furthermore, although FIG. 5 is shown including 2 shelves 350 a, 350 b, any number of shelves 350 may be used, including 2 support shelves, 3 support shelves, 4 support shelves, or 6 support shelves. In one or more embodiments a process kit includes the substrate support 230, the ring 420, the shelves 350, and the isolation plate 221.

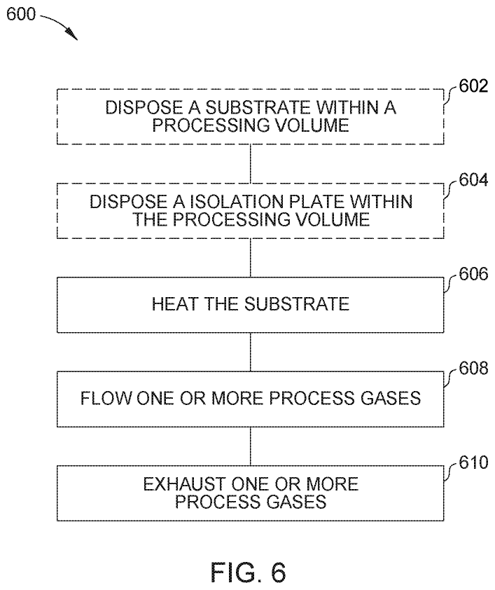

FIG. 6 is a schematic block diagram of a method 600 of loading an isolation plate 221 within an inner volume 203 of the processing chamber 2000, according to one or more embodiments. The method 600 may be performed using one or more components described herein.

At optional operation 602, a substrate is disposed within a processing volume using a robot arm. The robot arm inserts the substrate into the processing volume through an opening of the processing volume. The robot arm laterally inserts the substrate into the processing volume until the substrate is axially aligned with the substrate support. The robot arm then lowers the substrate onto a plurality of raised lift pins disposed on the substrate support. The substrate is lowered until the substrate is supported by the lift pins. The robot arm continues to lower and then laterally retreats from under the substrate without contacting the substrate in order to avoid damage. The lift pins are then lowered until the substrate is supported by a support face of the substrate support.

At optional operation 604, an isolation plate is disposed within the processing volume using a robot arm. It is contemplated that operation 604 may be performed using the same robot arm as the robot arm used in operation 602. In one or more embodiments, the robot arm used to perform operation 604 is different from the robot arm used to perform operation 602. The robot arm inserts the isolation plate into the processing volume through an opening of the processing volume. The robot arm laterally inserts the isolation plate into the processing volume until the isolation plate is aligned with the plurality of support shelves. The robot arm then lowers the isolation plate onto the plurality of support shelves. The isolation plate is lowered until a first outer surface and a second outer surface of the isolation plate contact the plurality of support shelves. The robot arm continues to lower and then laterally retreats from under the isolation plate without contacting the isolation plate in order to avoid damage. It is contemplated that in one or more embodiments, operation 602 is performed prior to operation 604. In one or more embodiments, operation 604 is performed prior to operation 602.

Operation 606 includes heating a substrate positioned on a substrate support. Operation 606 may be performed prior to, simultaneously with, and/or after operations 602, 604. Heating occurs via a plurality of heat sources (such as radiant heat sources), and to a predetermined temperature, as described above.

Operation 608 includes flowing one or more process gases over the substrate to form one or more layers on the substrate. The flowing of the one or more process gases over the substrate includes optionally guiding the one or more process gases through a rectangular flow opening of a flow guide insert. In one or more embodiments, the one or more process gases are supplied at a pressure that is 300 Torr or greater, such as within a range of 300 Torr to 600 Torr, or greater. Other pressures such as less than 1 Torr, for example 100 mTorr or less, may be used. In one or more embodiments, the one or more process gases are supplied at a flow rate that is less than 5,000 standard cubic centimeters per minute (SCCM). Other pressure values and flow rates are contemplated. In one or more embodiments, the substrate is rotated at a rotation speed that is less than 8 rotations-per-minute (RPM) during the flowing of the one or more process gases over the substrate. In one or more embodiments, the rotation speed is 1 RPM. Other rotation speeds (such as 16 RPM or 32 RPM) are contemplated.

Operation 610 includes exhausting the one or more process gases through an exhaust path formed at least partially in a sidewall.

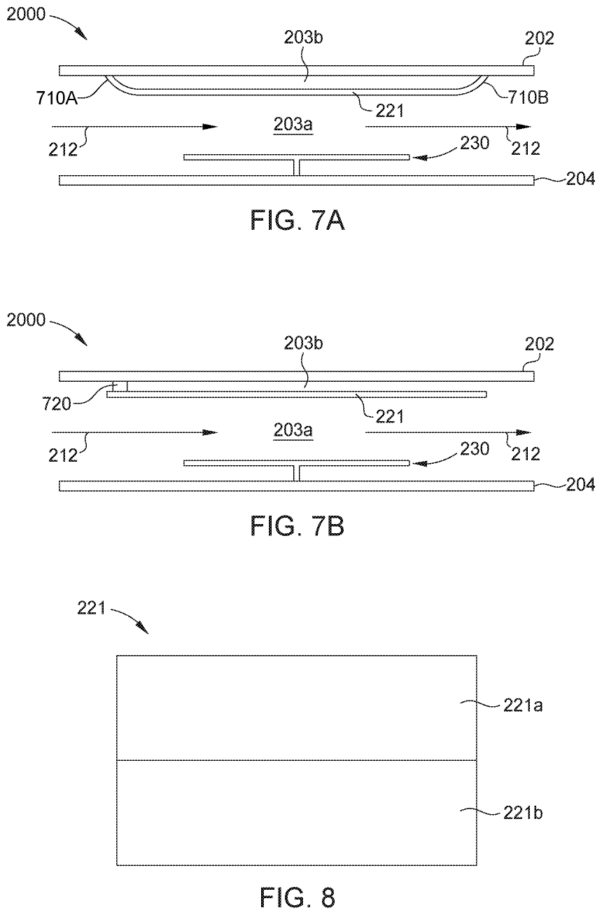

FIGS. 7A and 7B are schematic cross sectional side views of the process chamber 2000, according to embodiments. The isolation plate 221 shown in FIG. 7A includes a curved leading edge 710A, a curved trailing edge 710B, or a combination thereof. The curved leading edge 710A and/or the curved trailing edge 710B are curved towards the lower surface of the first plate 202. During a processing operation, as the process gas flows along the gas flow path 212, the curved leading edge 710A and/or the curved trailing edge 710B of the isolation plate 221 prevent the process gas from flowing into the upper inner volume 203b. In one or more embodiments, the curved leading edge 710A and/or the curved trailing edge 710B of the isolation plate 221 contact the lower surface of the first plate 202. In one or more embodiments, a gap separates the curved leading edge 710A and/or the curved trailing edge 710B of the isolation plate 221 from the lower surface of the first plate 202.

The process chamber 2000 shown in FIG. 7B includes one or more inner ribs 720 disposed on the lower surface of the first plate 202. During a processing operation, as the process gas flows along the gas flow path 212, the one or more inner ribs 720 prevent the process gas from flowing into the upper inner volume 203b. In one or more embodiments, the one or more inner ribs 720 contact the upper surface of the isolation plate 221. In one or more embodiments, a gap separates the one or more inner ribs 720 from the upper surface of the isolation plate 221.

FIG. 8 is a schematic top view of an isolation plate 221, according to embodiments. In one or more embodiments, the isolation plate 221 includes a first section 221a and a second section 221b. In one or more embodiments, the first section 221a and the second section 221b each include a quartz material. In one or more embodiments, the oxygen-hydrogen (OH) concentration (for example, a hydroxyl concentration) of the quartz material in the first section 221a is different from the OH concentration of the quartz material in the second section 221b. The variation in OH concentration between the first section 221a and the second section 221b results in different levels of transparency between the first section 221a and the second section 221b. For example, in one or more embodiments the first section 221a has a higher OH content than the second section 221b. The first section 221a may exhibit increased opacity or altered light transmission characteristics, while the second section 221b, with a lower OH concentration, remains more transparent. This differential transparency enables greater control over light propagation through the plate. It should be understood that although the isolation plate is shown having two sections 221a, 221b, the isolation plate 221 may include any number of sections such as 1 section, 2 sections, 3 sections, 4 sections, or 10 sections, for example.

Other processes may be performed before, during, or after the completion of the method 600. In one or more embodiments, purge gases may be flowed through the processing chamber during method 600. In one or more embodiments, cleaning gas may be flowed through the processing chamber after the completion of method 600.

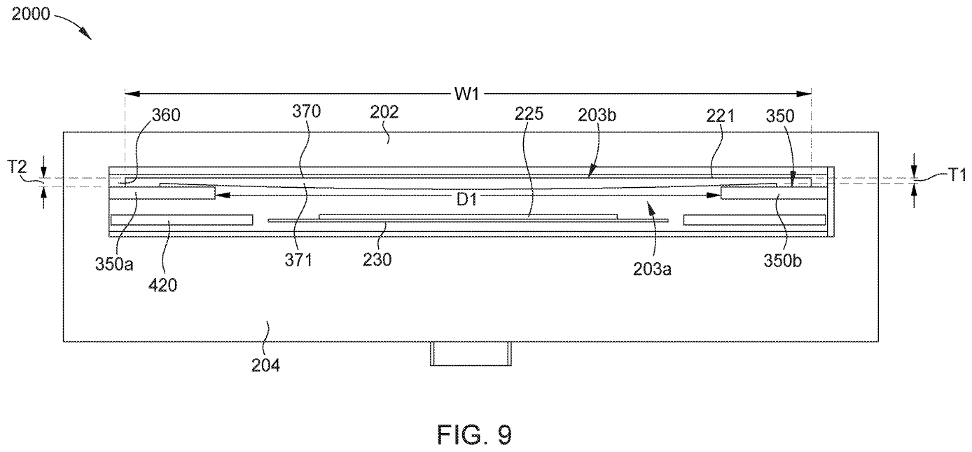

FIG. 9 is a schematic cross sectional front view of the process chamber 2000, according to one or more embodiments. In one or more embodiments, the isolation plate 221 includes one or more curved surfaces. For example, the isolation plate 221 shown in FIG. 9 includes a curved lower surface 371. The lower surface 371 may include a convex curve, or a concave curve. In one or more embodiments, upper surface 370 of the isolation plate incudes a curved geometry, such as a convex curve or a concave curve. In one or more embodiments, at least part of the isolation plate 221 is in the shape of a dome, such as a concave or convex dome.

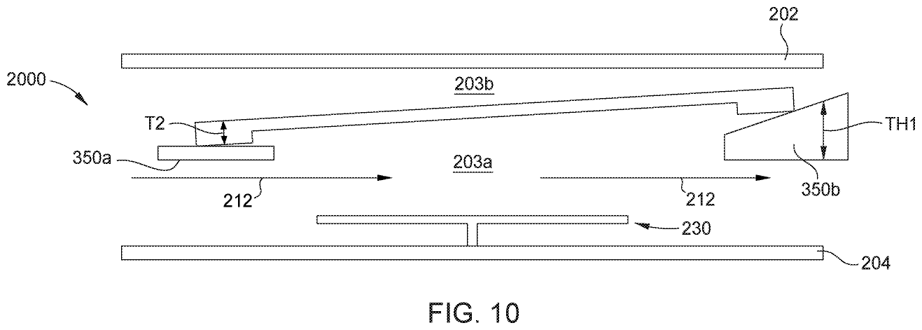

FIG. 10 cross sectional side views of the process chamber 2000, according to embodiments. The outer thickness T2 of the isolation plate 221 and/or at least one of the shelves 350 (as shown in FIG. 10) includes a gradient thickness (such as an incline that can be linear or nonlinear, such as curved, for example). The gradient thickness can increase or decrease along the length of the isolation plate 221, for example. The gradient can create a tilt or angle when the isolation plate 221 is supported on plurality of shelves 350. The present disclosure contemplates that the isolation plate 221 can be moved relative to the shelves 350 to adjust the tilt or angle. The gradient can allow the isolation plate 221 to be positioned at an adjusted inclination, in order to adjust and control the flow path of the process gas. In one or more embodiments, at least one of the plurality of shelves 350 includes a gradient thickness TH1 that increases or decreases along the length of the respective shelf 350.

Benefits of the present disclosure include mitigated effects of vortex flow, enhanced processing (e.g., deposition) thicknesses; enhanced processing (e.g., deposition) uniformities; reduced coating of chamber components (such as the isolation plate 221); adjustability of process parameters (such gas flow rate, temperature, and/or growth rate); reduced cleaning; increased throughput and efficiency; and reduced chamber downtime.

It is contemplated that one or more aspects disclosed herein may be combined. As an example, one or more aspects, features, components, operations and/or properties of the processing chamber 1000, the process kit 1010, the substrate support 106, the lift pins 132, the upper window 108, the lower window 110, the pre-heat ring 302, the isolation plate 321, the processing chamber 2000, the first plate 202, the second plate 204, the isolation plate 221, the substrate 225, the substrate support 230, the shelves 350, the inner sidewalls 360, the support shelves 450a-450d, the ring 420, the robot arm 510, the method 600, the curved edges 710A, 710B, the one or more inner ribs 720, the 221A, 221B, the 371, and/or the gradient thickness TH1 may be combined. Moreover, it is contemplated that one or more aspects disclosed herein may include some or all of the aforementioned benefits.

While the foregoing is directed to embodiments of the present disclosure, other and further embodiments of the disclosure may be devised without departing from the basic scope thereof, and the scope thereof is determined by the claims that follow.

What is claimed is:

1. A processing chamber, comprising:
a first plate, a second plate, and a plurality of sidewalls at least partially defining a processing volume;
a cover disposed above the first plate, the cover and the first plate at least partially defining an upper heating area;
a first energy module disposed within the upper heating area, the first energy module comprising a plurality of heating elements;
a substrate support disposed in the processing volume;
a plurality of ribs disposed around the first plate, the second plate, and the sidewalls;
a plurality of support shelves disposed opposite of one another within the processing volume; and
an isolation plate disposed within the processing volume and above the substrate support, an outer portion of a lower surface of the isolation plate supported by the plurality of shelves.

2. The processing chamber of claim 1, wherein a first support shelf of the plurality of support shelves is coupled to a first sidewall of the plurality of sidewalls and a second support shelf of the plurality of support shelves is coupled to a second sidewall of the plurality of sidewalls.

3. The processing chamber of claim 1, wherein the isolation plate is a flat plate.

4. The processing chamber of claim 1, wherein the isolation plate has an inner thickness at an inner section and an outer thickness at an outer section disposed radially outwardly of the inner section, wherein the inner thickness and the outer thickness are different from one another.

5. The processing chamber of claim 4, wherein the outer thickness is larger than the inner thickness.

6. The processing chamber of claim 1, wherein the isolation plate is formed of a quartz material.

7. The processing chamber of claim 1, wherein the plurality of support shelves are coupled to a ring surrounding the substrate support disposed within the processing volume.

8. The processing chamber of claim 1, wherein the plurality of support shelves are formed of a quartz material.

9. The processing chamber of claim 1, wherein a gap defined by an upper surface of the substrate and the lower surface of the isolation plate is greater than a thickness of a robot arm configured to dispose the isolation plate within the processing volume.

10. A process kit comprising;
a substrate support;
a ring sized and shaped to surround the substrate support;
a plurality of support shelves, the shelves respectively including a block having a thickness lesser than a length; and
an isolation plate sized and shaped for disposition on the plurality of support shelves.

11. The process kit of claim 10, wherein the isolation plate comprises one or more curved surfaces.

12. The process kit of claim 10, wherein the isolation plate has an inner thickness at an inner section and an outer thickness at an outer section disposed radially outwardly of the inner section, wherein the inner thickness and the outer thickness are different from one another.

13. The process kit of claim 10, wherein one or more of the isolation plate or at least one of the support shelves includes an incline to adjust a tilt of the isolation plate.

14. The process kit of claim 10, wherein the isolation plate comprises a plurality of sections that respectively include different oxygen-hydrogen (OH) concentrations.

15. The process kit of claim 10, wherein the plurality of support shelves are formed of a quartz material.

16. The process kit of claim 10, wherein the shelves respectively include a rectangular block.

17. A method of loading an isolation plate comprising:
disposing a substrate onto a substrate support within a processing volume using a robot arm;
disposing an isolation plate on a plurality of support shelves disposed within the processing volume using the robot arm;
heating the substrate positioned on the substrate support; and
flowing one or more process gases over the substrate to process the substrate, the flowing of the one or more process gases over the substrate comprising guiding the one or more process gases through one or more flow paths defined at least in part by a space between the isolation plate and the substrate.

18. The method of claim 17, wherein the robot arm disposes the substrate prior to disposing the isolation plate.

19. The method of claim 17, wherein the robot arm disposes the isolation plate prior to disposing the substrate.

20. The method of claim 17, wherein a gap defined by an upper surface of the substrate and the lower surface of the isolation plate is greater than a thickness of a robot arm.
